(19) United States
(12) Patent Application Publication
(10) Pub. No.: US 2024/0213740 A1
(43) Pub. Date: Jun. 27, 2024

(54) ELECTRO-ABSORPTION MODULATED DISTRIBUTED FEEDBACK LASER CHIP AND LASER CHIP ENCAPSULATION STRUCTURE

(71) Applicant: INNOLIGHT TECHNOLOGY (SUZHOU) LTD., Jiangsu (CN)

(72) Inventor: Zhenzhong WANG, Jiangsu (CN)

(73) Assignee: INNOLIGHT TECHNOLOGY (SUZHOU) LTD., Jiangsu (CN)

(21) Appl. No.: 18/429,371

(22) Filed: Jan. 31, 2024

Related U.S. Application Data
(63) Continuation of application No. PCT/CN2021/135602, filed on Dec. 6, 2021.

(30) Foreign Application Priority Data
Aug. 20, 2021 (CN) 202110962534.2

(51) Int. Cl. H01S 5/026; H01S 5/022; H01S 5/042; H01S 5/12

(52) U.S. Cl. CPC H01S 5/0265; H01S 5/022; H01S 5/04256; H01S 5/12

(57) ABSTRACT

An electro-absorption modulated distributed feedback laser chip includes a substrate having an upper surface and a lower surface opposite to each other, a laser-emitting portion located on the upper surface of the substrate and configured to emit a laser, a modulating portion located on the upper surface of the substrate and configured to modulate the laser emitted by the laser-emitting portion, a back metal electrode layer located on the lower surface of the substrate, a ground electrode located on the upper surface of the substrate, disposed near the modulating portion, and electrically connected to the back metal electrode layer, a signal electrode located on the upper surface of the substrate, disposed near the ground electrode and the modulating portion, and electrically connected to the modulating portion, and a waveguide structure coupled to the laser-emitting portion and the modulating portion. A laser chip encapsulation structure is also provided.

### CROSS-REFERENCE TO RELATED APPLICATION

This application is a continuation of international application of PCT application serial no. PCT/CN2021/135602, filed on Dec. 6, 2021, which claims the priority benefit of China application no. 202110962534.2, filed on Aug. 20, 2021. The entirety of each of the above mentioned patent applications is hereby incorporated by reference herein and made a part of this specification.

### TECHNICAL FIELD

The disclosure relates to the field of optical communication technology, and in particular to an electro-absorption modulated distributed feedback laser chip and a laser chip encapsulation structure.

### BACKGROUND TECHNIQUE

In the optical communication market, lasers are divided into vertical-cavity surface-emitting laser (VCSEL), distributed-feedback laser (DFB), electro-absorption modulated distributed feedback laser (EML), Mach-Zehnder modulator (MZM), and so on. High-speed optical transceiver devices are widely used in long-distance optical fiber transmission systems due to the advantages of high modulation bandwidth and low insertion loss. As data center applications develop, the need for high bandwidth laser chips arises. Generally, laser chips cannot be used directly, and the chips need to be encapsulated for signal transmission. The high-frequency performance of the laser chip depends on the encapsulation structure of the laser chip and the common performance of the laser chip.

However, the conventional laser chip encapsulation method generally uses leads to connect the chip electrodes. The laser chip and leads are both placed on the substrate, the radio frequency signal (RF) and the positive electrode of the laser chip are connected through the lead to form a loop path of the RF signal line. This encapsulation method requires a long lead to complete the electrical connection. The long lead generates a large parasitic inductance and hinders the transmission of high-frequency signals, thereby it is not conducive to improving the encapsulation bandwidth of the laser chip.

### SUMMARY OF THE INVENTION

### Technical problem

Based on the above, in order to solve the problems in the above background, it is necessary to provide an electro-absorption modulated distributed feedback laser chip and a laser chip encapsulation structure which shortens the transmission path of a signal circuit and a ground loop effectively, so that parasitic inductance generated by a lead is reduced, the encapsulation bandwidth of the laser chip is improved, and the laser chip is compatible with direct current and alternating current.

### Solution for the Problem

### Technical Solution

In order to solve the above technical problems, the first aspect of the disclosure proposes an electro-absorption modulated distributed feedback laser chip, which includes the following.

A substrate has an upper surface and a lower surface opposite to each other.

A laser-emitting portion is located on the upper surface of the substrate and configured to emit a laser.

A modulating portion is located on the upper surface of the substrate and configured to modulate the laser emitted by the laser-emitting portion.

A back metal electrode layer is located on the lower surface of the substrate.

A ground electrode is located on the upper surface of the substrate, disposed near the modulating portion, and electrically connected to the back metal electrode layer.

A signal electrode is located on the upper surface of the substrate, disposed near the ground electrode and the modulating portion, and electrically connected to the modulating portion.

A waveguide structure is coupled to the laser-emitting portion and the modulating portion.

The electro-absorption modulated distributed feedback laser provided in the above embodiment is electrically connected to the ground electrode disposed near the modulating portion, the ground electrode, and the back metal electrode layer. At the same time, a signal electrode is disposed near the ground electrode and the modulating portion, and the signal electrode is electrically connected to the modulating portion. After the chip is encapsulated, the transmission path of the signal circuit and the ground loop is shortened, so that the parasitic inductance generated by the lead is reduced, and the encapsulation bandwidth of the laser chip is improved.

In an embodiment, there are a plurality of ground electrodes, and the signal electrode is disposed between adjacent ground electrodes.

In an embodiment, the electro-absorption modulated distributed feedback laser chip further includes the following.

A matching resistor is formed in an area on the upper surface of the substrate near the modulating portion. An end of the matching resistor is configured to connect to the signal electrode, the matching resistor is integrated on the electro-absorption modulated distributed feedback laser chip, and in conjunction with the subsequent designed transmission wires within the encapsulation structure, the inductance property brought about by the encapsulation is effectively reduced.

In an embodiment, the matching resistor and the ground electrode are located on two sides of the waveguide structure.

The second aspect of the disclosure proposes a laser chip encapsulation structure, which includes the following.

A first substrate is provided.

A first metal electrode layer is located on the first substrate.

An electro-absorption modulated distributed feedback laser chip is located on the first metal electrode layer.

The electro-absorption modulated distributed feedback laser chip includes a substrate having an upper surface and a lower surface opposite to each other, a laser-emitting portion located on the upper surface of the substrate and configured to emit a laser, a modulating portion located on the upper surface of the substrate and configured to modulate the laser emitted by the laser-emitting portion, a ground electrode located on the upper surface of the substrate, disposed near the modulating portion, and electrically connected to the first metal electrode layer, a signal electrode located on the upper surface of the substrate, disposed near the ground electrode and the modulating portion, and electrically connected to the modulating portion.

A second substrate structure is located on the first metal electrode layer and disposed adjacent to the electro-absorption modulated distributed feedback laser chip.

A plurality of transmission lines are disposed on the second substrate structure and connected to the ground electrode and the signal electrode respectively.

In an embodiment, the second substrate structure includes a second substrate and a second metal electrode layer, in which the second substrate is located on the first metal electrode layer, and the second metal electrode layer is located between the first metal electrode layer and the second substrate.

In an embodiment, the thickness of the second substrate is consistent with the thickness of the electro-absorption modulated distributed feedback laser chip. The second substrate is disposed adjacent to the modulated distributed feedback laser chip, a gold wire connecting to an end of the signal line and the matching resistor is controlled to a shortest possible length, which reduces the transmission path of the signal circuit, so that parasitic inductance is reduced, and the encapsulation bandwidth of the electro-absorption modulated distributed feedback laser chip is improved.

In an embodiment, the electro-absorption modulated distributed feedback laser chip and the second substrate structure both have longitudinal structures and are arranged side by side.

In an embodiment, the transmission line includes a signal line, a first ground line, and a second ground line, in which the signal line is located between the first ground line and the second ground line, the signal line is connected to the signal electrode, and the first ground line and the second ground line are both connected to the ground electrode.

In an embodiment, the signal line is connected to the signal electrode via a gold wire, and the first ground line and the second ground line are connected to the ground electrode via a gold wire.

In an embodiment, at least one of the shape of the signal line, the shape of the first ground line, and the shape of the second ground line is formed in an L-shape.

In an embodiment, the signal line, the first ground line, and the second ground line are all disposed on the upper surface of the second substrate. The first ground line and the second ground line penetrate the second substrate and are communicated with the second metal electrode layer.

In an embodiment, the signal line is disposed on the upper surface of the second substrate, and the first ground line and the second ground line are located on two sides of the second substrate and both disposed on the second metal electrode layer.

In an embodiment, the second metal electrode layer extends to the two sides of the second substrate, the signal line is disposed on the upper surface of the second substrate, and portions of the second metal electrode layer extending to the two opposite sides of the second substrate form the first ground line and the second ground line.

In an embodiment, the electro-absorption modulated distributed feedback laser chip includes a matching resistor, an end of the matching resistor is disposed with a first pad, and another end of the matching resistor is disposed with a second pad. The first pad is connected to the first metal electrode layer via a gold wire, and the second pad is connected to the signal electrode via a gold wire.

In an embodiment, the electro-absorption modulated distributed feedback laser chip includes a matching resistor, an end of the matching resistor is disposed with a first pad, and another end of the matching resistor is disposed with a second pad. The laser chip encapsulation structure further includes a matching capacitance, and the matching capacitance is located on an upper surface of the first metal electrode layer and disposed adjacent to the electro-absorption modulated distributed feedback laser chip. A first end of the matching capacitance is connected to the first pad via a gold wire, and a second end of the matching capacitance is connected to the first metal electrode layer.

In the laser chip encapsulation structure provided in the above embodiment, the first metal electrode layer is located on the first substrate; the electro-absorption modulated distributed feedback laser chip is located on the first metal electrode layer; the back metal electrode layer in the electro-absorption modulated distributed feedback laser chip is in contact with the first metal electrode layer, in which the ground electrode in the electro-absorption modulated distributed feedback laser chip is electrically connected to the first metal electrode layer through the back metal electrode layer, the transmission line is connected to the ground electrode to form a ground loop, and compared with the ground loop in the existing encapsulation structure, the transmission path of the ground loop is significantly shortened and the parasitic inductance is reduced; and the second substrate structure is located on the first metal electrode layer and disposed adjacent to the electro-absorption modulated distributed feedback laser chip, the second substrate structure is disposed adjacent to the electro-absorption modulated distributed feedback laser chip, the transmission line is disposed on the second substrate structure, and the transmission line is connected to the signal electrode, which shortens the transmission path of the signal circuit effectively, so that parasitic inductance caused by a long lead is reduced. Based on the design from the two aspects, the transmission path of the ground loop and the signal circuit is shortened, the parasitic inductance is reduced, and the encapsulation bandwidth of the laser chip is improved.

The above description is merely an overview of the technical solutions of the disclosure. In order to have a clearer understanding of the technical means of the disclosure and implement the disclosure according to the content of the description, preferred embodiments of the disclosure are described in detail below with reference to the accompanying drawings.

### Advantageous Effect of the Invention

### Advantageous Effect

The electro-absorption modulated distributed feedback laser chip and the laser chip encapsulation structure disclosed in the disclosure can effectively shorten the transmission paths of the radio frequency signal line and the ground loop, reduce the impact of parasitic inductance generated by leads on the high frequency signal transmission of the chip, improve the encapsulation bandwidth of the electro-absorption modulated distributed feedback laser chip and be compatible with direct current and alternating current.

### BRIEF DESCRIPTION OF THE DRAWINGS

### Description of the Drawings

In order to describe the technical solutions of the embodiments of the disclosure clearly, the drawings needed to be used in the description of the embodiments will be briefly introduced below. Certainly, the drawings in the following description are merely some embodiments of the disclosure. For persons of ordinary skill in the art, drawings of other embodiments may be obtained based on the drawings without exerting creative efforts.

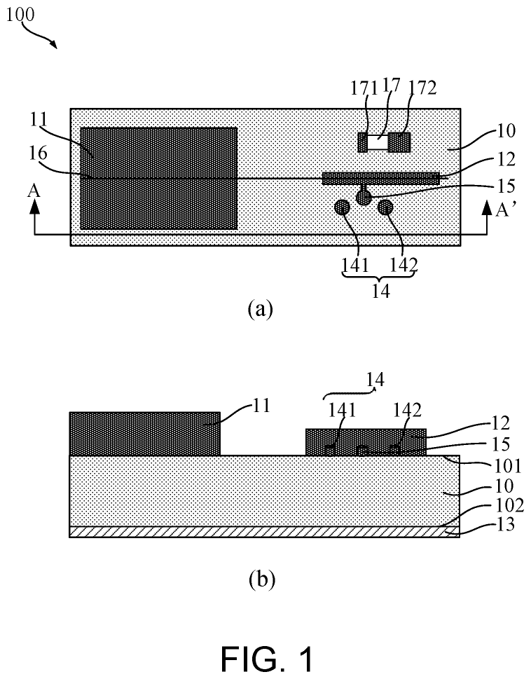

FIG. 1 is a schematic structural view of an electro-absorption modulated distributed feedback laser chip according to an embodiment of the disclosure, in which (a) in FIG. 1 is a schematic top view of the electro-absorption modulated distributed feedback laser chip, and (b) in FIG. 1 is a schematic cross-sectional view of the electro-absorption modulated distributed feedback laser chip taken along a direction AA′ in (a) in FIG. 1.

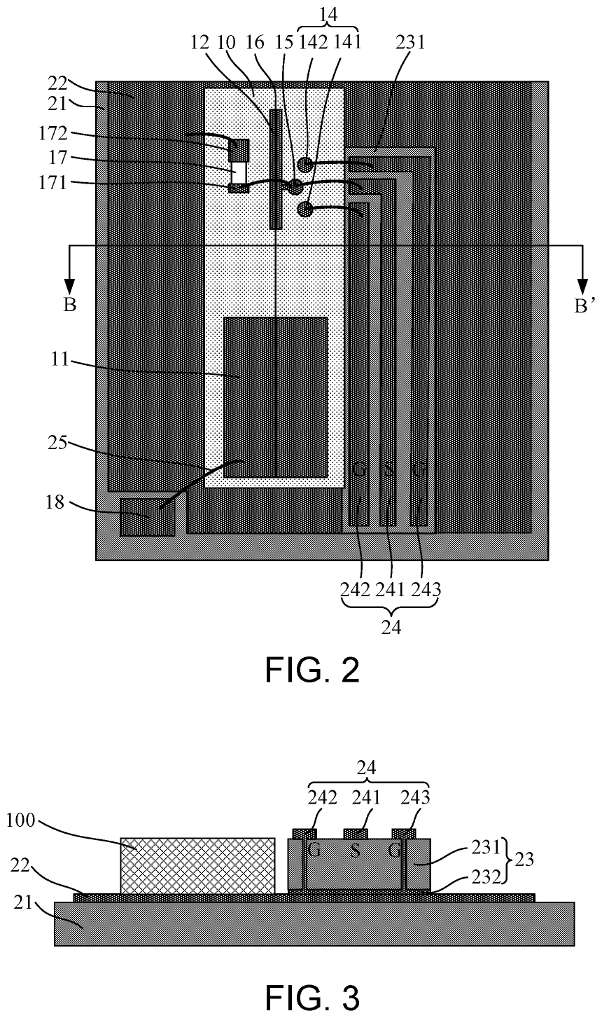

FIG. 2 is a schematic top view of a laser chip encapsulation structure according to an embodiment of the disclosure.

FIG. 3 is a partial cross-sectional structural view of the laser chip encapsulation structure taken along a BB′ direction in FIG. 2 according to an embodiment of the disclosure.

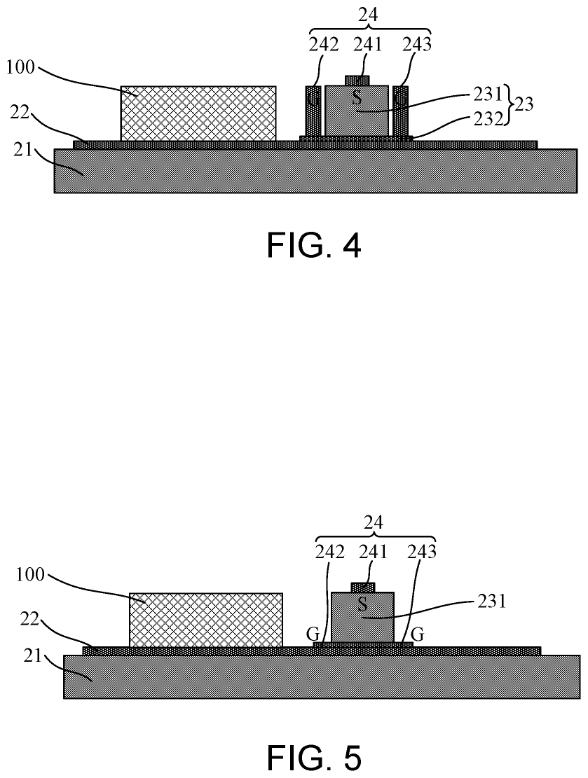

FIG. 4 is a partial cross-sectional structural view of the laser chip encapsulation structure taken along the BB′ direction in FIG. 2 according to another embodiment of the disclosure.

FIG. 5 is a partial cross-sectional structural view of the laser chip encapsulation structure taken along the BB′ direction in FIG. 2 according to still another embodiment of the disclosure.

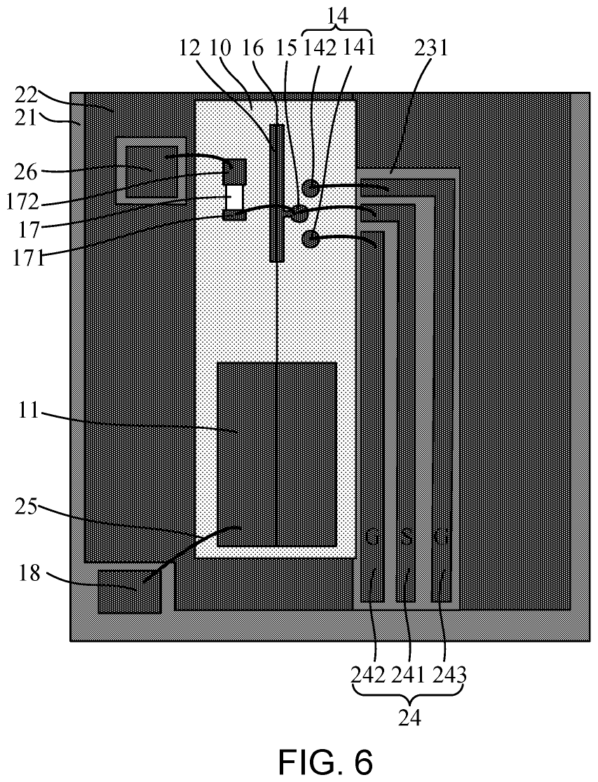

FIG. 6 is a schematic top view of the laser chip encapsulation structure according to another embodiment of the disclosure.

Description of reference numerals: 100: electro-absorption modulated distributed feedback laser chip; 10: substrate; 101: upper surface; 102: lower surface; 11: laser-emitting portion; 12: modulating portion; 13: back metal electrode layer;

14: ground electrode; 141: first ground electrode; 142: second ground electrode;

15: signal electrode; 16: waveguide structure;

17: matching resistor; 171: first pad; 172: second pad;

18: chip anode;

21: first substrate; 22: first metal electrode layer;

23: second substrate structure; 231: second substrate; 232: second metal electrode layer;

24: transmission line; 241: signal line; 242: first ground line; 243: second ground line;

25: gold wire;

26: matching capacitance.

### Embodiments of the Invention

### The Implementation of the Disclosure

In order to facilitate understanding of the disclosure, the disclosure will be described more fully below with reference to the relevant drawings. Preferred embodiments of the disclosure are shown in the accompanying drawings. However, the disclosure may be implemented in many different forms and is not limited to the embodiments described herein. Rather, the embodiments are provided so that this disclosure will be thorough and complete.

Unless otherwise defined, all technical and scientific terms used herein have the same meaning as commonly understood by persons of ordinary skill in the technical field to which the disclosure belongs. The terminology used herein in the description of the application is for the purpose of describing specific embodiments merely and is not intended to limit the disclosure. As used herein, the term “and/or” includes any and all combinations of one or more of the related listed items.

It will be understood that when an element or layer is referred to as being “on,” “adjacent,” “connected to”, or “coupled to” another element or layer, the element or layer may be directly on, adjacent to, connected to, connected or coupled to the other element or layer, or there may be intervening elements or layers. In contrast, when an element is referred to as being “directly on,” “directly adjacent,” “directly connected to”, or “directly coupled to” another element or layer, there are no intervening elements or layers. It will be understood that, although the terms first, second, third, etc. may be used to describe various elements, components, regions, layers, and/or sections, the elements, components, regions, layers, and/or sections should not be limited by the terms. The terms are merely used to distinguish an element, component, region, layer, or section from another element, component, region, layer, or section. Thus, a first element, component, region, layer, or section discussed below may be termed as a second element, component, region, layer, or section without departing from the teachings of the disclosure.

Spatial relational terms such as “under”, “below”, “underneath”, “beneath”, “on”, “above” may be used herein for convenience of description to describe the relationship of an element or feature to other elements or features shown in the drawings. It will be understood that the spatially relative terms are intended to encompass different orientations of the device in use and operation in addition to the orientation shown in the drawings. For example, if a device in the drawing is turned over, then elements or features described as “below” or “under” or “beneath” other elements or features would then be oriented “above” the other elements or features. Thus, the exemplary terms “below” and “under” may include both upper and lower orientations. The device may be otherwise oriented (rotated 90 degrees or at other orientations) and the spatial descriptions used herein are interpreted accordingly.

The terminology used herein is for the purpose of describing particular embodiments merely and is not intended to be limiting of the disclosure. As used herein, the singular forms “a,” “an,” and “the” are intended to include the plural forms as well, unless the context clearly dictates otherwise. It will also be understood that the terms “including” and/or “comprising”, when used in the description, the presence of stated features, integers, steps, operations, elements, and/or parts are confirmed but the presence or addition of one or more features, integers, steps, operations, elements, parts, and/or groups are not excluded. When used herein, the term “and/or” includes any and all combinations of the related listed items.

Embodiments of the disclosure are described herein with reference to cross-sectional views of schematic illustrations of idealized embodiments (and intermediate structures) of the disclosure. Thus, variations of shapes shown may be anticipated due to, for example, manufacturing techniques and/or tolerances. Accordingly, embodiments of the disclosure should not be limited to the particular shapes of the areas shown herein but include deviations in shapes due to, for example, manufacturing. The areas shown in the drawings are schematic in nature and shapes thereof are not intended to show the actual shapes of the regions of the device and are not intended to limit the scope of the disclosure.

In an embodiment of the disclosure, as shown in FIG. 1, an electro-absorption modulated distributed feedback laser chip 100 is provided, which includes a substrate 10, a laser-emitting portion 11, a modulating portion 12, a back metal electrode layer 13, a ground electrode 14, a signal electrode 15, and a waveguide structure 16. The substrate 10 has an upper surface 101 and a lower surface 102 opposite to each other. The laser-emitting portion 11 is located on the upper surface of the substrate 10 and configured to emit a laser. The modulating portion 12 is located on the upper surface of the substrate 10 and configured to modulate the laser emitted by the laser-emitting portion 11. The back metal electrode layer 13 is located on the lower surface of the substrate 10. The ground electrode 14 is located on the upper surface of the substrate 10, disposed near the modulating portion 12, and electrically connected to the back metal electrode layer 13. The signal electrode 15 is located on the upper surface of the substrate 10, disposed near the ground electrode 14 and the modulating portion 12, and electrically connected to the modulating portion 12. The waveguide structure 16 is coupled to the laser-emitting portion 11 and the modulating portion 12. In the embodiment, the back metal electrode layer 13 is a metal layer formed on the lower surface 102 of the substrate 10. In other embodiments, the back metal electrode layer 13 may also be an electrical connection point located on the lower surface 102.

The electro-absorption modulated distributed feedback laser provided in the above embodiment is electrically connected to the ground electrode disposed near the modulating portion, the ground electrode, and the back metal electrode layer. At the same time, a signal electrode is disposed near the ground electrode and the modulating portion, and the signal electrode is electrically connected to the modulating portion. After the chip is encapsulated, the transmission path of the signal circuit and the ground loop is shortened, so that the parasitic inductance generated by the lead is reduced, and the encapsulation bandwidth of the laser chip is improved.

As an example, the substrate 10 may include, but is not limited to, an InP substrate; the laser-emitting portion 11 may include, but is not limited to, a distributed-feedback laser (DFB), and the modulating portion 12 may include, but is not limited to, an electro-absorption modulator (EAM). The laser-emitting portion 11 emits a laser after being excited by a DC current. When passing through the modulating portion 12, the laser is modulated by the radio frequency signal added to the modulating portion 12. The modulating portion 12 emits the modulated laser through an optical link. The cathode of the laser-emitting portion 11 is connected to the cathode of the modulating portion 12 and together serve as the ground electrode 14. The waveguide structure 16 may include, but is not limited to, a rectangular optical waveguide or a ridge optical waveguide, and is configured to transmit the laser emitted by the laser-emitting portion 11.

In an embodiment, there are multiple ground electrodes 14, and the signal electrodes 15 are disposed between adjacent ground electrodes 14. Please continue to refer to FIG. 1. The ground electrode 14 includes a first ground electrode 141 and a second ground electrode 142. The first ground electrode 141 and the second ground electrode 142 are respectively disposed on two opposite sides of the signal electrode 15. It may be understood that FIG. 1 is merely used as an example for explanation, and the specific number of ground electrodes 14 is not limited. As an example, the signal electrode 15 may be the anode of the electro-absorption modulated distributed feedback laser chip 100.

As an example, the ground electrode 14 may be electrically connected to the back metal electrode layer 13 along a side wall of the substrate 10, so that after the laser chip is encapsulated, the ground electrode 14 is connected to the first metal electrode layer to form a ground loop, which reduces the length of the gold wire, thereby the parasitic inductance of the gold wire is reduced, and the encapsulation bandwidth of the laser chip is improved. The ground electrode 14 and the back metal electrode layer 13 may also be connected in a manner that a through hole (not shown in FIG. 1) that penetrates the substrate 10 is formed without damaging the substrate 10, and the through hole may be filled with a conductive material to substitute the gold wire conduction method, which can further reduce the parasitic inductance. Specifically, the conductive material may include, but is not limited to, gold, copper, aluminum, silver, or metal alloys in any combination of the above, and the like. The ground electrode 14 may be fixed to the upper surface of the substrate 10 using a metal pad, so that the gold wire 25 may be used as a bridge to connect the ground electrode 14 with the transmission line in series to form a path.

Please continue to refer to FIG. 1. In an embodiment, the electro-absorption modulated distributed feedback laser chip 100 further includes a matching resistor 17. The matching resistor 17 is formed in an area on the upper surface of the substrate 10 near the modulating portion 12. An end of the matching resistor 17 is configured to connect to the signal electrode 15 to reduce high-frequency reflection caused by the capacitance characteristics of the modulating portion 12. Specifically, an end of the matching resistor 17 is provided with a first pad 171, and another end of the matching resistor 17 is provided with a second pad 172. As an example, the first pad 171 and the second pad 172 both include metal pads, and the materials of the metal pads may include, but are not limited to, gold, copper, aluminum, silver, or metal alloys in any combination of the above, and the like.

In an embodiment, the matching resistor 17 and the ground electrode 14 are located on two sides of the waveguide structure 16. The resistance value of the matching resistor 17 can be appropriately adjusted to eliminate or minimize the problem of signal reflection at the interface caused by the mismatch between the impedance on the transmission line 24 and the internal impedance of the electro-absorption modulated distributed feedback laser chip 100, thereby improving the signal transmission efficiency, so that before the electro-absorption modulated distributed feedback laser chip 100 is encapsulated, the maximum transmission power of the laser chip can be obtained. Moreover, when the laser chip is subsequently encapsulated, the size of the overall encapsulation structure can be reduced and the cost is reduced, which is beneficial to the preparation of small-sized chip encapsulation structures.

In an embodiment of the disclosure, as shown in FIG. 2, a laser chip encapsulation structure is also provided, which includes a first substrate 21, a first metal electrode layer 22, the electro-absorption modulated distributed feedback laser chip 100, a second substrate structure 23, and multiple transmission lines 24. The first metal electrode layer 22 is located on the first substrate 21; the electro-absorption modulated distributed feedback laser chip 100 is located on the first metal electrode layer 22, in which the back metal electrode layer 13 is in contact with the first metal electrode layer 22; the second substrate structure 23 is located on the first metal electrode layer 22 and is disposed adjacent to the electro-absorption modulated distributed feedback laser chip 100; and a plurality of transmission lines 24 are disposed on the second substrate structure 23 and connected to the ground electrode 14 and the signal electrode 15 respectively.

In the laser chip encapsulation structure provided in the above embodiment, the first metal electrode layer is located on the first substrate; the electro-absorption modulated distributed feedback laser chip is located on the first metal electrode layer; the back metal electrode layer in the electro-absorption modulated distributed feedback laser chip is in contact with the first metal electrode layer, in which the ground electrode in the electro-absorption modulated distributed feedback laser chip is electrically connected to the first metal electrode layer through the back metal electrode layer, the transmission line is connected to the ground electrode to form a ground loop, and compared with the ground loop in the existing encapsulation structure, the transmission path of the ground loop is significantly shortened and the parasitic inductance is reduced; and the second substrate structure is located on the first metal electrode layer and disposed adjacent to the electro-absorption modulated distributed feedback laser chip, the second substrate structure is disposed adjacent to the electro-absorption modulated distributed feedback laser chip, the transmission line is disposed on the second substrate structure, and the transmission line is connected to the signal electrode, which can shorten the transmission path of the signal circuit effectively, so that the parasitic inductance caused by the long lead is reduced. Based on the design from the two aspects, the transmission path of the ground loop and the signal circuit is shortened, the overall parasitic inductance is reduced, and the encapsulation bandwidth of the laser chip is improved.

Please continue to refer to FIG. 2. In an embodiment, the second substrate structure 23 includes a second substrate 231 and a second metal electrode layer 232. The second substrate 231 is located on the first metal electrode layer 22. The second metal electrode layer 232 is located between the first metal electrode layer 22 and the second substrates 231. The electro-absorption modulated distributed feedback laser chip 100 and the second substrate structure 23 both have longitudinal structures and are arranged side by side near each other, which can reduce the length of the gold wire 25 connecting the signal electrode 15 and the matching resistor 17.

As an example, both the first substrate 21 and the second substrate 231 may include, but are not limited to, ceramic substrates (AIN); both the first metal electrode layer 22 and the second metal electrode layer 232 may include, but are not limited to, gold, copper, aluminum, silver, or metal alloys in any combination of the above, and the like. Specifically, the first metal electrode layer 22 and the second metal electrode layer 232 are both electrode layers after patterning and serve as the ground end of the electro-absorption modulated distributed feedback laser chip 100 and the ground end of the transmission line 24 respectively, thereby a ground loop and a signal circuit (or radio frequency signal circuit) are formed.

As an example, the first metal electrode layer 22 and the second metal electrode layer 232 may be prepared by, but are not limited to, spin coating method or carbon brush electrode method, and optionally, the spin coating method is adopted for the preparation.

As an example, the thicknesses of the first metal electrode layer 22 and the second metal electrode layer 232 may be the same or different. Please refer to FIG. 3. The thickness of the second substrate 231 is consistent with the thickness of the laser chip 100 to eliminate the height difference between the transmission line and the laser chip in the conventional method, which reduces the length of the gold wire 25 and reduces the parasitic inductance generated by the gold wire 25, and the encapsulation bandwidth of the laser chip is improved.

Please refer to FIG. 2 and FIG. 3. In an embodiment, the transmission line 24 includes a signal line 241, a first ground line 242, and a second ground line 243. The signal line 241 is located between the first ground line 242 and the second ground line 243, in which the signal line 241 is connected to the signal electrode 15, and the first ground line 242 and the second ground line 243 are both connected to the ground electrode 14.

As an example, the radio frequency signal RF conducted by the signal line 241 may be any type of modulation signal, such as a sinusoidal signal or a square wave signal, which is not limited by the comparison of the embodiments of the disclosure.

Specifically, please refer to FIG. 2 and FIG. 3. The signal line 241 is connected to the signal electrode 15 via the gold wire 25, and the first ground line 242 and the second ground line 243 are connected to the ground electrode 14 via the gold wire 25. The first ground line 242 is connected to the first ground electrode 141 via the gold wire 25, and the second ground line 243 is connected to the second ground electrode 142 via the gold wire 25. As an example, at least one of the shape of the signal line 241, the shape of the first ground line 242, and the shape of the second ground line 243 is formed in an L-shape, in which the first ground line 242 is formed in a cylindrical shape, and the signal wire 241 and the second ground line 243 are both formed in an L-shape.

In an embodiment, an end of the matching resistor 17 is disposed with a first pad 171, and another end of the matching resistor 17 is disposed with a second pad 172. The first pad 171 is connected to the first metal electrode layer 22 via the gold wire 25, and the second pad 172 is connected to the signal electrode 15 via the gold wire 25.

Please refer to FIG. 3. In an embodiment, the thickness of the second substrate 231 is consistent with the thickness of the electro-absorption modulated distributed feedback laser chip 100, so that the transmission line 24 and the electro-absorption modulated distributed feedback laser chip 100 are on the same horizontal plane. The second substrate 231 is disposed adjacent to the electro-absorption modulated distributed feedback laser chip 100 so that the gold wire 25 connecting to the signal line 241 and an end of the matching resistor 17 is controlled to the shortest possible length, which can significantly shorten the transmission path of the signal circuit, thereby the parasitic inductance is reduced, the encapsulation bandwidth of the electro-absorption modulated distributed feedback laser chip 100 is improved, and at the same time it is beneficial to improving the mechanical stability of the overall encapsulation structure.

As an example, please continue to refer to FIG. 2. The chip anode 18 disposed on the substrate 10 is connected to the laser-emitting portion 11 via the gold wire 25.

The electrical connection method between the transmission line 24 and the second metal electrode layer 232 according to the disclosure includes situations as follows.

In an embodiment, as shown in FIG. 3, the signal line 241, the first ground line 242, and the second ground line 243 are all disposed on the upper surface of the second substrate 231. The first ground line 242 and the second ground line 243 penetrate the second substrate 231 and are communicated with the second metal electrode layer 232.

In an embodiment, as shown in FIG. 4, the signal line 241 is disposed on the upper surface of the second substrate 231, the first ground line 242 and the second ground line 243 are located on two sides of the second substrate 231 and both disposed on the second metal electrode layer 232.

In an embodiment, as shown in FIG. 5, the second metal electrode layer 232 extends to two sides of the second substrate 231, the signal line 241 is disposed on the upper surface of the second substrate 231, and portions of the second metal electrode layer 232 extending to the two opposite sides of the second substrate 231 form the first ground line 242 and the second ground line 243.

In the laser chip encapsulation structure according to an embodiment of the disclosure, the technical effects are as follows. The matching resistor 17 is integrated on the electro-absorption modulated distributed feedback laser chip 100, the matching resistor 17 is separated from the ground electrode 14, and the matching resistor 17 and the ground electrode 14 are located on two sides of the waveguide structure 16. The first ground loop is formed by the first ground line 242, the gold wire 25, the first ground electrode 141, and the first metal electrode layer 22, the second ground loop is formed by the second ground line 243, the second ground electrode 142, and the first metal electrode layer 22, the signal circuit is formed by the signal line 241, the gold wire 25, the signal electrode 15, the second pad 172, the matching resistor 17, the first pad 171, the gold wire 25, and the first metal electrode layer 22. The thickness of the second substrate 231 is consistent with the thickness of the electro-absorption modulated distributed feedback laser chip 100. Compared with the matching resistor being disposed on the substrate in the conventional manner and the conventional ground loop and the radio frequency signal circuit, the length of the gold wire is significantly reduced and the parasitic inductance generated by the gold wire is reduced, thereby the encapsulation bandwidth of the laser chip is improved.

In another embodiment, as shown in FIG. 6, the laser chip encapsulation structure further includes a matching capacitance 26. The matching capacitance 26 is located on an upper surface of the first metal electrode layer 22 and disposed adjacent to the electro-absorption modulated distributed feedback laser chip 100. The first end of the matching capacitance 26 is connected to the first pad 171 via the gold wire 25, and the second end of the matching capacitance 26 is connected to the first metal electrode layer 22. The matching capacitance 26 is an external capacitor located outside the electro-absorption modulated distributed feedback laser chip 100, which enables the laser chip encapsulation structure to have low power consumption, allow alternating current to pass, and not affect the high-frequency performance of the electro-absorption modulated distributed feedback laser chip 100. When matching capacitance 26 is not added, the laser chip encapsulation structure allows direct current to pass.

In an embodiment, the electro-absorption modulated distributed feedback laser chip 100 may also be integrated with a DFB chip, an EAM chip, and a semiconductor optical amplifier (SOA). Specifically, the workflow of the electro-absorption modulated distributed feedback laser chip 100 may be that the laser generated by the DFB chip is amplified by the SOA chip, modulated by the EAM chip, and then output. Alternatively, the laser generated by the DFB chip may also be modulated by EAM, amplified by the SOA chip, and then output.

Please note that the embodiments are merely for illustrative purposes and are not intended to limit the disclosure.

Each embodiment in this specification is described in a progressive manner. Each embodiment focuses on differences from other embodiments. The same and similar parts between the various embodiments may be referred to each other.

The technical features of the embodiments may be combined in any way. To simplify the description, not all possible combinations of the technical features in the embodiments are described. However, as long as there is no contradiction in the combination of the technical features, all of the combinations should be considered to be within the scope of this disclosure.

The embodiments merely express several implementation manners of the disclosure, and the descriptions thereof are specific and detailed, but the descriptions should not be construed as limiting the scope of the disclosure. It should be noted that, for persons of ordinary skill in the art, several modifications and improvements may be made without departing from the concept of the disclosure, and the modifications and improvements all belong to the protection scope of the disclosure. Therefore, the scope of protection of the disclosure should be determined by the appended claims.

What is claimed is:

1. An electro-absorption modulated distributed feedback laser chip, comprising:
a substrate having an upper surface and a lower surface opposite to each other;
a laser-emitting portion located on the upper surface of the substrate and configured to emit a laser;
a modulating portion located on the upper surface of the substrate and configured to modulate the laser emitted by the laser-emitting portion;
a back metal electrode layer located on the lower surface of the substrate;
a ground electrode located on the upper surface of the substrate, disposed near the modulating portion, and electrically connected to the back metal electrode layer;
a signal electrode located on the upper surface of the substrate, disposed near the ground electrode and the modulating portion, and electrically connected to the modulating portion; and
a waveguide structure coupled to the laser-emitting portion and the modulating portion.

2. The electro-absorption modulated distributed feedback laser chip of claim 1, wherein there are a plurality of ground electrodes, and the signal electrode is disposed between the adjacent ground electrodes.

3. The electro-absorption modulated distributed feedback laser chip of claim 1, wherein the electro-absorption modulated distributed feedback laser chip further comprises:
a matching resistor formed in an area on the upper surface of the substrate near the modulating portion, and an end of the matching resistor is configured to connect to the signal electrode.

4. The electro-absorption modulated distributed feedback laser chip of claim 3, wherein the matching resistor and the ground electrode are located at two sides of the waveguide structure.

5. A laser chip encapsulation structure, comprising:
a first substrate;
a first metal electrode layer located on the first substrate;
an electro-absorption modulated distributed feedback laser chip located on the first metal electrode layer, the electro-absorption modulated distributed feedback laser chip comprising:
a substrate having an upper surface and a lower surface opposite to each other, a laser-emitting portion located on the upper surface of the substrate and configured to emit a laser, a modulating portion located on the upper surface of the substrate and configured to modulate the laser emitted by the laser-emitting portion, a ground electrode located on the upper surface of the substrate, disposed near the modulating portion, and electrically connected to the first metal electrode layer, and a signal electrode located on the upper surface of the substrate, disposed near the ground electrode and the modulating portion, and electrically connected to the modulating portion;
a second substrate structure located on the first metal electrode layer and disposed adjacent to the electro-absorption modulated distributed feedback laser chip; and
a plurality of transmission lines disposed on the second substrate structure and connected to the ground electrode and the signal electrode respectively.

6. The laser chip encapsulation structure of claim 5, wherein the second substrate structure comprises a second substrate and a second metal electrode layer, the second substrate is located on the first metal electrode layer, and the second metal electrode layer is located between the first metal electrode layer and the second substrate.

7. The laser chip encapsulation structure of claim 6, wherein a thickness of the second substrate is consistent with a thickness of the electro-absorption modulated distributed feedback laser chip.

8. The laser chip encapsulation structure of claim 6, wherein the electro-absorption modulated distributed feedback laser chip and the second substrate structure both have longitudinal structures and are arranged side by side.

9. The laser chip encapsulation structure of claim 6, wherein the plurality of transmission lines comprises a signal line, a first ground line, and a second ground line, the signal line is located between the first ground line and the second ground line, the signal line is connected to the signal electrode, and the first ground line and the second ground line are both connected to the ground electrode.

10. The laser chip encapsulation structure of claim 9, wherein the signal line is connected to the signal electrode via a gold wire, and the first ground line and the second ground line are connected to the ground electrode via a gold wire.

11. The laser chip encapsulation structure of claim 9, wherein at least one of a shape of the signal line, a shape of the first ground line, and a shape of the second ground line is formed in an L-shape.

12. The laser chip encapsulation structure of claim 9, wherein the signal line, the first ground line, and the second ground line are all disposed on an upper surface of the second substrate, and the first ground line and the second ground line penetrate the second substrate to connect with the second metal electrode layer.

13. The laser chip encapsulation structure of claim 9, wherein the signal line is disposed on an upper surface of the second substrate, and the first ground line and the second ground line are located on two sides of the second substrate and are both disposed on the second metal electrode layer.

14. The laser chip encapsulation structure of claim 9, wherein the second metal electrode layer extends to two opposite sides of the second substrate, the signal line is disposed on an upper surface of the second substrate, and portions of the second metal electrode layer extending to the two opposite sides of the second substrate form the first ground line and the second ground line.

15. The laser chip encapsulation structure of claim 5, wherein the electro-absorption modulated distributed feedback laser chip comprises a matching resistor, an end of the matching resistor has a first pad, the other end of the matching resistor has a second pad, the first pad is connected to the first metal electrode layer via a gold wire, and the second pad is connected to the signal electrode via a gold wire.

16. The laser chip encapsulation structure of claim 5, wherein the electro-absorption modulated distributed feedback laser chip comprises a matching resistor, an end of the matching resistor has a first pad, the other end of the matching resistor has a second pad, the laser chip encapsulation structure further comprises a matching capacitance, the matching capacitance is located on an upper surface of the first metal electrode layer and disposed adjacent to the electro-absorption modulated distributed feedback laser chip, a first end of the matching capacitance is connected to the first pad via a gold wire, and a second end of the matching capacitance is connected to the first metal electrode layer.
